(19) United States
(12) Patent Application Publication
(10) Pub. No.: US 2008/0157108 A1
(43) Pub. Date: Jul. 3, 2008

(54) Light-Emitting Diode and Method for Manufacturing the Same

(75) Inventors: Kuo-Hui Yu, Chia Yi Hsien (TW); Yung-Hsin Shie, Kaohsiung City (TW); Cheng-Ta Kuo, Hsinchu City (TW); Yu-Cheng Yang, Yongkang City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: EPITECH TECHNOLOGY CORPORATION, Tainan County (TW)

(21) Appl. No.: 11/669,576

(22) Filed: Jan. 31, 2007

(30) Foreign Application Priority Data
Dec. 27, 2006 (TW) 95149362

(51) Int. Cl. H01L 33/00

(52) U.S. Cl. 257/98

(57) ABSTRACT

A light-emitting diode (LED) and a method for manufacturing the same are described. The light-emitting diode comprises a substrate, a reflective structure, a buffer layer and an illuminant epitaxial structure. The reflective structure is deposed on a surface of the substrate, wherein the reflective structure includes a plurality of openings set therein to define the reflective structure as a regular pattern structure and to expose a portion of the surface of the substrate. The buffer layer is deposed on the reflective structure and the exposed portion of the surface of the substrate, and fills the openings. The illuminant epitaxial structure is deposed on the buffer layer.

### RELATED APPLICATIONS

The present application is based on, and claims priority from, Taiwan Application Serial Number 95149362, filed Dec. 27, 2006, the disclosure of which is hereby incorporated by reference herein in its entirety.

### FIELD OF THE INVENTION

The present invention relates to a light-emitting device, and more particularly, to a light-emitting diode (LED) and a method for manufacturing the same.

### BACKGROUND OF THE INVENTION

Semiconductor light-emitting devices such as light emitting diodes (LED), are formed by using semiconductor materials. Semiconductor light emitting devices are minute solid-state light sources that transform electrical energy into light energy. Semiconductor light emitting devices are small in volume, use a low driving voltage, have a rapid response speed, are shockproof, and are long-lived. Semiconductor light emitting devices are also light, thin, and small thereby meeting the needs of various apparatuses, and thus have been widely applied in various electric products used in daily life.

Currently, when a light-emitting diode is fabricated, a layer of AlInGaN is formed directly on a substrate as a buffer layer by a low temperature growth method. However, dislocation defect density in the buffer layer greatly increases, resulting in a reduction in the life of the light-emitting device and the degradation of the performance of the light-emitting device.

Thus, it is desirable for a light-emitting diode to offer high axial light extraction, high luminescence efficiency, better operation performance and have longer life to meet increasingly strict requirements in the market.

### SUMMARY OF THE INVENTION

One aspect of the present invention is to provide a light-emitting diode, in which a reflective structure with a regular pattern is deposed between a substrate and an illuminant epitaxial structure, so that the axial light extraction of the light-emitting diode is greatly increased to enhance luminescence efficiency and brightness of the device.

Another aspect of the present invention is to provide a light-emitting diode, in which a plurality of openings are formed in a reflective structure between a substrate and an illuminant epitaxial structure to make the reflective structure be a cyclically arranged structure, so that the light scattering is effected to further increase the light extraction of the light-emitting diode.

Still another aspect of the present invention is to provide a method for manufacturing a light-emitting diode, in which a buffer layer and an illuminant epitaxial structure are grown on a substrate and a reflective structure by an epitaxial lateral overgrowth (ELO) method, so that the dislocation defect density in the buffer layer and the illuminant epitaxial structure is reduced to offer the high quality epitaxial structure, thereby increasing the operation stability of the light-emitting diode and prolonging the life of the device.

According to the aforementioned aspects, the present invention provides a light-emitting diode, comprising: a substrate; a reflective structure deposed on a surface of the substrate, wherein the reflective structure includes a plurality of openings set therein to define the reflective structure as a regular pattern structure and to expose a portion of the surface of the substrate; a buffer layer deposed on the reflective structure and the exposed portion of the surface of the substrate, and filling the openings; and an illuminant epitaxial structure deposed on the buffer layer.

According to a preferred embodiment of the present invention, the reflective structure is a distributed bragg reflector (DBR) structure.

According to another preferred embodiment of the present invention, the reflective structure is a one-dimensional photonic crystal reflector (PCR) structure.

According to the aforementioned aspects, the present invention further provides a method for manufacturing a light-emitting diode, comprising: providing a substrate; forming a reflective structure on a surface of the substrate, wherein the reflective structure is set with a plurality of openings to define the reflective structure as a regular pattern structure and to expose a portion of the surface of the substrate; forming a buffer layer on the reflective structure and the exposed portion of the surface of the substrate and filling the openings; and forming an illuminant epitaxial structure on the buffer layer.

According to a preferred embodiment of the present invention, the step of forming the buffer layer is performed by an epitaxial lateral overgrowth method.

According to another preferred embodiment of the present invention, the step of forming the illuminant epitaxial structure is performed by an epitaxial lateral overgrowth method.

According to the aforementioned aspects, the present invention further provides a light-emitting diode, comprising: a substrate, wherein a plurality of holes are formed in a portion of a surface of the substrate to make a surface structure of the substrate with a regular pattern; a reflective structure deposed on the other portion of the surface of the substrate; a buffer layer deposed on the reflective structure and the holes of the substrate and filling the holes; and an illuminant epitaxial structure deposed on the buffer layer.

According to the aforementioned aspects, the present invention further provides a method for manufacturing a light-emitting diode, comprising: providing a substrate; forming a reflective layer to cover a surface of the substrate; performing a pattern defining step to form a plurality of holes in the reflective layer and the substrate, so as to define the reflective layer into a reflective structure with a regular pattern; forming a buffer layer to cover the reflective structure and the holes of the substrate and to fill the holes; and forming an illuminant epitaxial structure on the buffer layer.

According to the aforementioned aspects, the present invention further provides a light-emitting diode, comprising: a substrate, wherein a plurality of holes are formed in a portion of a surface of the substrate to make a surface structure of the substrate with a regular pattern; a reflective structure deposed on bottoms of the holes; a buffer layer deposed on the reflective structure and the holes of the substrate and filling the holes; and an illuminant epitaxial structure deposed on the buffer layer.

According to the aforementioned aspects, the present invention further provides a method for manufacturing a light-emitting diode, comprising: providing a substrate; performing a pattern defining step to form a plurality of holes in a surface of the substrate, so as to make a surface structure of the substrate with a regular pattern; forming a reflective structure on bottoms of the holes; forming a buffer layer to cover the reflective structure and the holes of the substrate and to fill the holes; and forming an illuminant epitaxial structure on the buffer layer.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIGS. 1 through 3 are schematic flow diagrams showing the process for manufacturing a light-emitting diode in accordance with a preferred embodiment of the present invention;

FIGS. 4 through 6 are schematic flow diagrams showing the process for manufacturing a light-emitting diode in accordance with another preferred embodiment of the present invention; and

FIGS. 7 and 8 are schematic flow diagrams showing the process for manufacturing a light-emitting diode in accordance with still another preferred embodiment of the present invention.

### DETAILED DESCRIPTION OF THE PREFERRED EMBODIMENT

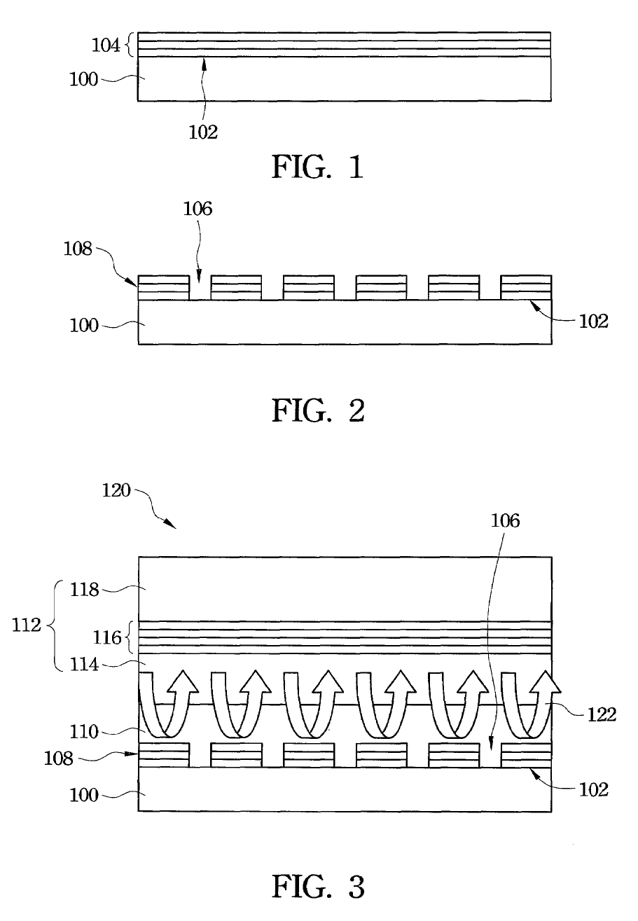

The present invention discloses a light-emitting diode and a method for manufacturing the same. In the light-emitting diode, a cyclically arranged reflective structure is deposed between a substrate and an illuminant epitaxial structure, and the quality of the illuminant epitaxial structure is superior, so that the light extraction of the light-emitting diode is greatly increased, the life of the device is prolonged and the operation quality of the device is enhanced. In order to make the illustration of the present invention more explicit, the following description is stated with reference to FIG. 1 through FIG. 8.

FIG. 1 through FIG. 3 are schematic flow diagrams showing the process for manufacturing a light-emitting diode in accordance with a preferred embodiment of the present invention. In the fabrication of a light-emitting diode, a substrate 100 is provided for the epitaxial growth of material layers formed thereon. A reflective layer 104 is deposited to completely cover a surface 102 of the substrate 100, such as shown in FIG. 1. In the exemplary embodiment, the reflective layer 104 may be composed of several layers of oxide films, wherein the oxide films are stacked on one another on the surface 102 of the substrate 100. The reflective layer 104 is preferably a multi-layer stacked structure with high reflectivity, such as a distributed bragg reflector structure or a one-dimensional photonic crystal reflector structure.

Then, a pattern defining step is performed on the reflective layer 104 to remove a portion of the reflective layer 104 by, for example, a photolithography and etching method, so as to form a reflective structure 108 including a plurality of openings 106 formed thereon, wherein the openings 106 expose a portion of the surface 102 of the substrate 100, such as shown in FIG. 2. In an exemplary embodiment, the pattern defining step is performed by a dry etching method or a wet etching method. By the pattern defining step, the reflective layer 104 is patterned to form the reflective structure 108 with a cyclically arranged pattern.

After the reflective structure 108 with the regular pattern is formed, a buffer layer 110 is grown to cover the reflective structure 108 and the exposed portion of the surface 102 of the substrate 100 and to fill all of the openings 106 by, for example, an epitaxial method. In the present exemplary embodiment, the buffer layer 110 may be grown by an epitaxial lateral overgrowth method. The buffer layer 110 can be grown along the lattice direction of the substrate 100 by using the epitaxial lateral overgrowth method, so that the dislocation defect density in the buffer layer 110 is effectively reduced to form the buffer layer 110 with a high quality epitaxial lateral overgrowth structure.

Next, an illuminant epitaxial structure 112 is grown on the buffer layer 10 by, for example, an epitaxial method. The illuminant epitaxial structure 112 comprises a first conductivity type semiconductor layer 114, an active layer 116 and a second conductivity type semiconductor layer 118. In the fabrication of the illuminant epitaxial structure 112, the first conductivity type semiconductor layer 114 is first epitaxially grown on the buffer layer 110 on the substrate 100, the active layer 116 is epitaxially grown on the first conductivity type semiconductor layer 114, and then the second conductivity type semiconductor layer 118 is epitaxially grown on the active layer 116. At present, the main structure of a light-emitting diode 120 is completed, such as shown in FIG. 3. The first conductivity type semiconductor layer 114 and the second conductivity type semiconductor layer 118 are different conductivity types. For example, while the first conductivity type is N-type, the second conductivity type is P-type; and while the first conductivity type is P-type, the second conductivity type is N-type. In the exemplary embodiment, the first conductivity type is N-type, and the second conductivity type is P-type. In the exemplary embodiment, the illuminant epitaxial structure 112 may be grown by an epitaxial lateral overgrowth method similarly. Accordingly, the dislocation defect density in the illuminant epitaxial structure 112 is reduced similarly and results in an illuminant epitaxial structure 112 with a high quality epitaxial lateral overgrowth structure.

Referring to FIG. 3, because the reflective structure 108 is located between the illuminant epitaxial structure 112 and the substrate 100, and the reflective structure 108 including the openings 106 therein is defined with a regular pattern, the light 112 emitted by the active layer 116 toward the substrate 100 can be effectively reflected by the reflective structure 108, thereby increasing the axial light extraction of the light-emitting diode 120. Additionally, the reflective structure 108 is a cyclically arranged structure, so that the light 122 emitted toward the substrate 100 is scattered caused by the rugged surface 102 of the reflective structure 108 to further increase the light extraction effect of the light-emitting diode 120, thereby enhancing luminescence efficiency and brightness of the device. Furthermore, the buffer layer 110 and the illuminant epitaxial structure 112 are grown by an epitaxial lateral overgrowth method, so that the dislocation defect density in the buffer layer 110 and the illuminant epitaxial structure 112 is reduced similarly and results in a high quality buffer layer 110 and the high quality illuminant epitaxial structure 112, thereby enhancing the operating stability and prolonging the life of the light-emitting diode 120.

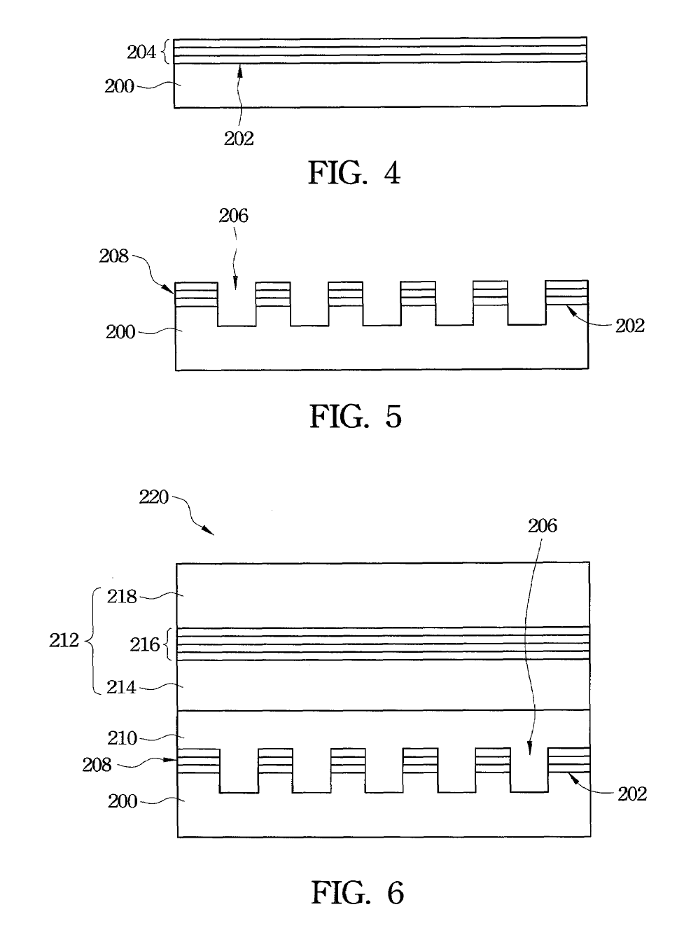

FIG. 4 through FIG. 6 are schematic flow diagrams showing the process for manufacturing a light-emitting diode in accordance with another preferred embodiment of the present invention. In the fabrication of a light-emitting diode, a substrate 200 is provided for the epitaxial growth of material layers formed thereon. A reflective layer 204 is deposited to completely cover a surface 202 of the substrate 200, such as shown in FIG. 4. In the exemplary embodiment, the reflective layer 204 may be composed of several layers of oxide films, wherein the oxide films are stacked on each other on the surface 202 of the substrate 200. The reflective layer 204 is preferably a multi-layer stacked structure with high reflectivity, such as a distributed bragg reflector structure or a one-dimensional photonic crystal reflector structure.

Next, a pattern defining step is performed on the reflective layer 204 and the substrate 200 to remove a portion of the reflective layer 204 and a portion of the substrate 200 by, for example, a photolithography and etching method, so as to form a plurality of holes 206 extending in the reflective layer 204 and the substrate 200 to make a surface structure of the substrate 200 with a regular pattern and to define the reflective layer 204 into a reflective structure 208 with a regular pattern, such as shown in FIG. 5. In the exemplary embodiment, the holes 206 are located on a portion of the surface 202 of the substrate 200, and the reflective structure 208 is located on the other portion of the surface 202 of the substrate 200. In the present invention, the pattern defining step is performed by a dry etching method or a wet etching method. The pattern defining step patterns the reflective layer 204 to form the reflective structure 208 with a cyclically arranged pattern.

Then, a buffer layer 210 is grown to cover the reflective structure 208 and the holes 206 in the substrate 200 and to fill all of the holes 206 by, for example, an epitaxial method. In the present exemplary embodiment, the buffer layer 210 may be grown by an epitaxial lateral overgrowth method. The buffer layer 210 can be grown along the lattice direction of the substrate 200 by using the epitaxial lateral overgrowth method, so that the dislocation defect density in the buffer layer 210 is effectively reduced to form the buffer layer 210 with a high quality epitaxial lateral overgrowth structure.

Then, an illuminant epitaxial structure 212 is grown on the buffer layer 210 by, for example, an epitaxial method. The illuminant epitaxial structure 212 comprises a first conductivity type semiconductor layer 214, an active layer 216 and a second conductivity type semiconductor layer 218. In the fabrication of the illuminant epitaxial structure 212, the first conductivity type semiconductor layer 214 is first epitaxially grown on the buffer layer 210 on the substrate 200, the active layer 216 is epitaxially grown on the first conductivity type semiconductor layer 214, and then the second conductivity type semiconductor layer 218 is epitaxially grown on the active layer 216. At present, the main structure of a light-emitting diode 220 is completed, such as shown in FIG. 6. The first conductivity type semiconductor layer 214 and the second conductivity type semiconductor layer 218 are different conductivity types. For example, while the first conductivity type is N-type, the second conductivity type is P-type; and while the first conductivity type is P-type, the second conductivity type is N-type. In the exemplary embodiment, the illuminant epitaxial structure 212 may be grown by an epitaxial lateral overgrowth method similarly. Accordingly, the dislocation defect density in the illuminant epitaxial structure 212 is reduced similarly to form the illuminant epitaxial structure 212 with a high quality epitaxial lateral overgrowth structure.

Because the reflective structure 208 is located between the illuminant epitaxial structure 212 and the substrate 200, and the reflective structure 208 is defined with a regular pattern, the light emitted by the active layer 216 toward the substrate 200 can be effectively reflected by the reflective structure 208, thereby increasing the axial light extraction of the light-emitting diode 220. Additionally, the reflective structure 208 and the surface 202 of the substrate 200 are cyclically arranged structures, so that the light emitted toward the substrate 200 is scattered by the rugged surface structures of the reflective structure 208 and the substrate 200 to further increase the light extraction effect of the light-emitting diode 220, thereby enhancing luminescence efficiency and brightness of the device. Moreover, the buffer layer 210 and the illuminant epitaxial structure 212 are grown by an epitaxial lateral overgrowth method, so that the dislocation defect density in the buffer layer 210 and the illuminant epitaxial structure 212 is reduced and results in a high quality buffer layer 210 and a high quality illuminant epitaxial structure 212, thereby enhancing the operating stability and prolonging the life of the light-emitting diode 220.

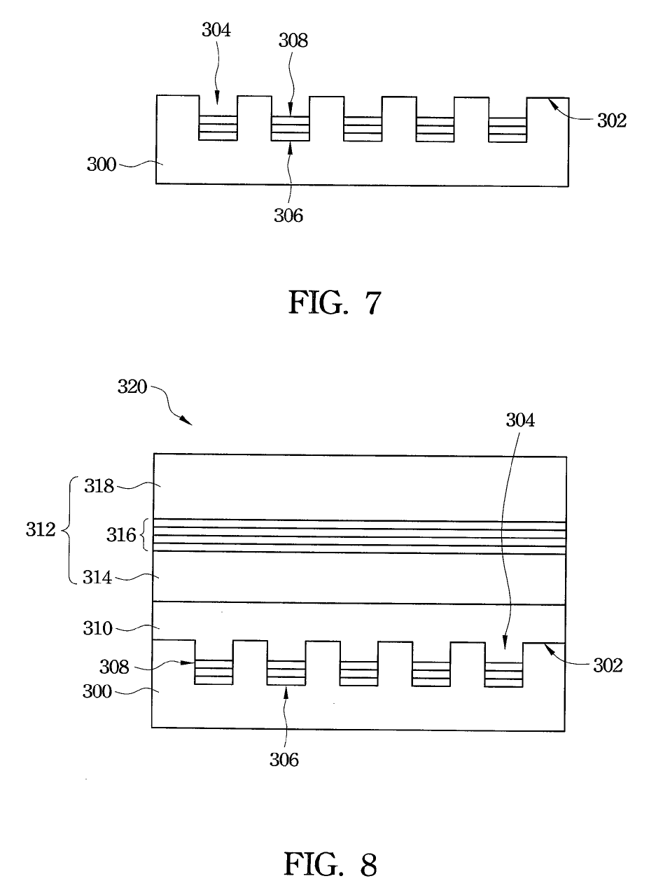

FIG. 7 and FIG. 8 are schematic flow diagrams showing the process for manufacturing a light-emitting diode in accordance with still another preferred embodiment of the present invention. In the fabrication of a light-emitting diode, a substrate 300 is provided for the epitaxial growth of material layers formed thereon. Next a pattern defining step is performed on a surface 302 of the substrate 300 to remove a portion of the substrate 300 by, for example, a photolithography and etching method, so as to form a plurality of holes 304 in the surface 302 of the substrate 300. In the present invention, the pattern defining step is performed by a dry etching method or a wet etching method. By the pattern defining step, the surface 302 of the substrate 300 is patterned to have a surface structure with a cyclically arranged pattern, so that a reflective structure 308 deposed on bottoms 306 of the holes 304 is formed with a regular pattern. Then, the reflective structure 308 is deposited on the bottoms 304 of the holes 306, such as shown in FIG. 7. In the exemplary embodiment, the reflective structure 308 may be composed of several layers of oxide films, wherein the oxide films are stacked one each other on the bottoms 306 of the holes 304 of the substrate 300. The reflective structure 308 is preferably a multi-layer stacked structure with high reflectivity, such as a distributed bragg reflector structure or a one-dimensional photonic crystal reflector structure.

A buffer layer 310 is grown to cover the reflective structure 308 and the holes 304 in the substrate 300 and to fill all of the holes 304 by, for example, an epitaxial method. In the present exemplary embodiment, the buffer layer 310 may be grown by an epitaxial lateral overgrowth method. The buffer layer 310 can be grown along the lattice direction of the substrate 300 by using the epitaxial lateral overgrowth method, so that the dislocation defect density in the buffer layer 310 is effectively reduced to form the buffer layer 310 with a high quality epitaxial lateral overgrowth structure. Then, an illuminant epitaxial structure 312 is grown on the buffer layer 310 by, for example, an epitaxial method. The illuminant epitaxial structure 312 comprises a first conductivity type semiconductor layer 314, an active layer 316 and a second conductivity type semiconductor layer 318. In the fabrication of the illuminant epitaxial structure 312, the first conductivity type semiconductor layer 314 is first epitaxially grown on the buffer layer 310, the active layer 316 is epitaxially grown on the first conductivity type semiconductor layer 314, and then the second conductivity type semiconductor layer 318 is epitaxially grown on the active layer 316. At present, the main structure of a light-emitting diode 320 is completed, such as shown in FIG. 7. The first conductivity type semiconductor layer 314 and the second conductivity type semiconductor layer 318 are different conductivity types. For example, while the first conductivity type is N-type, the second conductivity type is P-type; and while the first conductivity type is P-type, the second conductivity type is N-type. In the exemplary embodiment, the first conductivity type is N-type, and the second conductivity type is P-type. In the exemplary embodiment, the illuminant epitaxial structure 312 may be grown by an epitaxial lateral overgrowth method similarly. Accordingly, the dislocation defect density in the illuminant epitaxial structure 312 is reduced similarly to form an illuminant epitaxial structure 312 with a high quality epitaxial lateral overgrowth structure.

Because the reflective structure 308 is located between the illuminant epitaxial structure 312 and the substrate 300, and the reflective structure 308 is formed with a regular pattern by being deposed in the holes 304 of the substrate 300, the light emitted by the active layer 316 toward the substrate 300 can be effectively reflected by the reflective structure 308, thereby increasing the axial light extraction of the light-emitting diode 320. Additionally, the reflective structure 308 and the surface 302 of the substrate 300 are cyclically arranged structures, so that the light emitted toward the substrate 300 is scattered caused by the rugged surface structures of the reflective structure 308 and the substrate 300 to further increase the light extraction effect of the light-emitting diode 320, thereby enhancing luminescence efficiency and brightness of the device. Moreover, the buffer layer 310 and the illuminant epitaxial structure 312 are grown by an epitaxial lateral overgrowth method, so that the dislocation defect density in the buffer layer 310 and the illuminant epitaxial structure 312 is reduced similarly to offer the high quality buffer layer 310 and the high quality illuminant epitaxial structure 312, thereby enhancing the operating stability and prolonging the life of the light-emitting diode 320.

According to the aforementioned description, in the light-emitting diode of an exemplary embodiment of the present invention, a reflective structure with a regular pattern is deposed between a substrate and an illuminant epitaxial structure, so that the axial light extraction of the light-emitting diode is greatly increased to enhance luminescence efficiency and brightness of the device.

According to the aforementioned description, in the light-emitting diode of an exemplary embodiment of the present invention, a plurality of openings are formed in a reflective structure deposed between a substrate and an illuminant structure to make the reflective structure be a cyclically arranged structure, so that the light scattering effect is offered to further increase the light extraction of the light-emitting diode.

According to the aforementioned description, in the method for manufacturing a light-emitting diode of an exemplary embodiment of the present invention, a buffer layer and an illuminant epitaxial structure are grown by an epitaxial lateral overgrowth method, so that the dislocation defect density in the buffer layer and the illuminant epitaxial structure is reduced to offer the high quality epitaxial structure, thereby increasing the operation stability of the light-emitting diode and prolonging the life of the device.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

1. A light-emitting diode, comprising:
a substrate;
a reflective structure deposed on a surface of the substrate, wherein the reflective structure includes a plurality of openings set therein to define the reflective structure as a regular pattern structure and to expose a portion of the surface of the substrate;
a buffer layer deposed on the reflective structure and the exposed portion of the surface of the substrate, and filling the openings; and
an illuminant epitaxial structure deposed on the buffer layer.

2. The light-emitting diode according to claim 1, wherein the reflective structure comprises a plurality of oxide films stacked with one another.

3. The light-emitting diode according to claim 1, wherein the reflective structure is a distributed bragg reflector structure or a one-dimensional photonic crystal reflector structure.

4. The light-emitting diode according to claim 1, wherein the illuminant epitaxial structure comprises a first conductivity type semiconductor layer, an active layer and a second conductivity type semiconductor layer stacked on the buffer layer in sequence, and the first conductivity type semiconductor layer and the second conductivity type semiconductor layer are different conductivity types.

5. The light-emitting diode according to claim 1, wherein the illuminant epitaxial structure is an epitaxial lateral overgrowth structure, and the buffer is an epitaxial lateral overgrowth layer.

6-11. (canceled)

12. A light-emitting diode, comprising:
a substrate, wherein a plurality of holes are set in a portion of a surface of the substrate to make the substrate have a surface structure with a regular pattern;
a reflective structure deposed on the surface of the substrate and not in the holes set in the substrate;
a buffer layer deposed on the reflective structure and the holes of the substrate, and filling the holes; and
an illuminant epitaxial structure deposed on the buffer layer.

13. The light-emitting diode according to claim 12, wherein the reflective structure comprises a plurality of oxide films stacked with one another.

14. The light-emitting diode according to claim 12, wherein the reflective structure is a distributed bragg reflector structure or a one-dimensional photonic crystal reflector structure.

15. The light-emitting diode according to claim 12, wherein the illuminant epitaxial structure is an epitaxial lateral overgrowth structure, and the buffer is an epitaxial lateral overgrowth layer.

16-19. (canceled)

20. A light-emitting diode, comprising:
a substrate, wherein a plurality of holes are set in a portion of a surface of the substrate to make the substrate have a surface structure with a regular pattern;
a reflective structure deposed on bottoms of the holes;
a buffer layer deposed on the reflective structure and the holes of the substrate, and filling the holes; and
an illuminant epitaxial structure deposed on the buffer layer.

21. The light-emitting diode according to claim 20, wherein the reflective structure comprises a plurality of oxide films stacked with one another.

22. The light-emitting diode according to claim 20, wherein the reflective structure is a distributed bragg reflector structure or a one-dimensional photonic crystal reflector structure.

23. The light-emitting diode according to claim 20, wherein the illuminant epitaxial structure is an epitaxial lateral overgrowth structure, and the buffer is an epitaxial lateral overgrowth layer.

24-27. (canceled)
